(19) United States
(12) Patent Application Publication
(10) Pub. No.: US 2026/0011633 A1
(43) Pub. Date: Jan. 8, 2026

(54) HIGH DIE STACK PACKAGE WITH MODULAR STRUCTURE

(71) Applicant: Micron Technology, Inc., Boise, ID (US)

(72) Inventors: Kelvin Tan Aik Boo, Singapore (SG); Seng Kim Ye, Singapore (SG); Hong Wan Ng, Singapore (SG); Chin Hui Chong, Singapore (SG)

(21) Appl. No.: 19/260,100

(22) Filed: Jul. 3, 2025

Related U.S. Application Data
(60) Provisional application No. 63/668,764, filed on Jul. 8, 2024.

(51) Int. Cl. H01L 23/498; H01L 23/00; H01L 23/31; H01L 23/49; H01L 23/538; H01L 25/16

(52) U.S. Cl. CPC H01L 23/49838; H01L 23/3107; H01L 23/49; H01L 23/538; H01L 24/48; H01L 25/16; H01L 2224/48157

(57) ABSTRACT

Systems, devices, and methods for high die stack packages with modular structures are provided herein. A die stack package can include a substrate, a proximal unit carried by the substrate, and a distal unit carried by the proximal unit. The proximal unit can include first and second proximal die stacks, a proximal portion of a modular structure, and proximal wire bonds electrically coupling the first and second proximal die stacks to conducting elements of the modular structure. The distal unit can include first and second distal die stacks, a distal portion of the modular structure, and distal wire bonds electrically coupling the first and second distal die stacks to the conducting elements of the modular structure. In some embodiments, the die stack package further includes one or more modular units stacked between the proximal unit and the distal unit.

### CROSS-REFERENCE TO RELATED APPLICATION(S)

The present application claims priority to U.S. Provisional Patent Application No. 63/668,764, filed Jul. 8, 2024, the disclosure of which is incorporated herein by reference in its entirety.

### TECHNICAL FIELD

The present disclosure generally relates to semiconductor device assemblies, and more particularly relates to high die stack packages with modular structures.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1A is a partially schematic cross-sectional diagram of a die stack package including two die stacks.

FIG. 1B is a partially schematic cross-sectional diagram of a die stack package including four die stacks.

FIG. 2 is a partially schematic cross-sectional diagram of a die stack package configured in accordance with embodiments of the present technology.

FIG. 3 is a partially schematic plan view of an input-and-output extender configured in accordance with embodiments of the present technology.

FIGS. 4A and 4B are partially schematic cross-sectional views of a modular structure configured in accordance with embodiments of the present technology.

FIG. 5 is a partially schematic cross-sectional diagram of another die stack package configured in accordance with embodiments of the present technology.

FIG. 6 is a partially schematic cross-sectional diagram of another die stack package configured in accordance with embodiments of the present technology.

FIG. 7 is a partially schematic cross-sectional diagram of yet another die stack package configured in accordance with embodiments of the present technology.

FIG. 8 is a flowchart illustrating a method for manufacturing a die stack package in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

The demand for more dies in semiconductor packages is driven by the increasing need for higher performance, greater functionality, and improved energy efficiency in modern electronic devices. As applications in fields like artificial intelligence, high-performance computing, and mobile technology evolve, the necessity for integrating more computational power, more memory and/or storage, and specialized functions within a single package has grown significantly. However, as more dies are integrated into a single package, the physical space occupied by semiconductor packages and the necessary interconnections between dies become more problematic. This can lead to challenges in maintaining signal integrity, managing thermal dissipation, and ensuring reliable power delivery. Additionally, as the package becomes denser, the complexity of routing signals between the dies and the external connections increases.

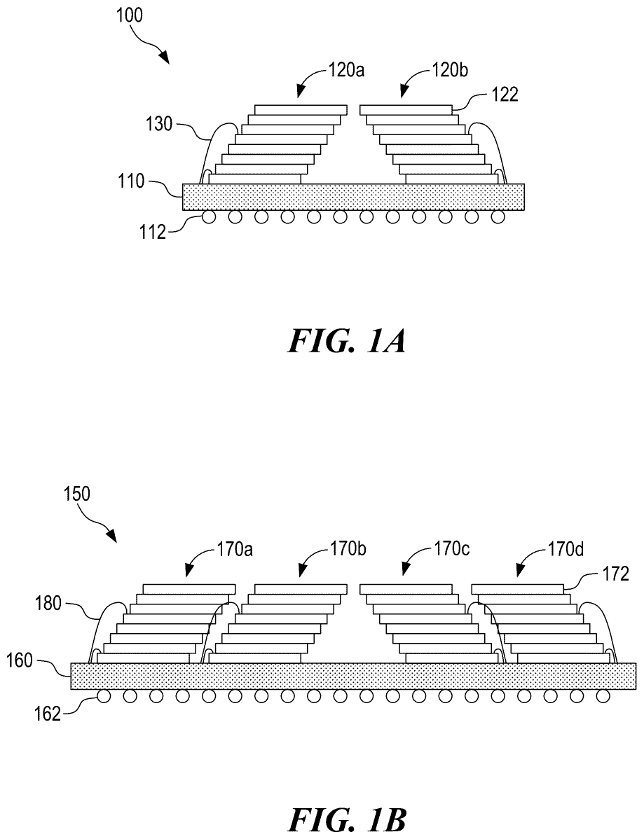

FIG. 1A is a partially schematic cross-sectional diagram of a die stack package 100. The die stack package 100 includes a substrate 110, a first die stack 120a, and a second die stack 120b. The substrate 110 can be coupled to other components not shown (e.g., a package substrate) via interconnections 112 (e.g., solder balls) such that the die stack package 100 can form part of a system-in-package (SiP). Each of the first die stack 120a and the second die stack 120b is carried by the substrate 110 such that the first die stack 120a and the second die stack 120b are arranged side-by-side. The first die stack 120a and the second die stack 120b can each include a plurality of dies 122 (in the illustrated embodiment, each die stack includes eight dies) stacked on top of one another in a cascading arrangement (e.g., forming steps), as illustrated. Also, one or more of the dies 122 in each of the first die stack 120a and the second die stack 120b can be electrically coupled to the substrate 110 via corresponding wire bonds 130. In particular, the wire bonds 130 can be coupled to portions of the upper surfaces of the one or more dies 122 that are exposed by virtue of the cascading arrangement.

FIG. 1B is a partially schematic cross-sectional diagram of a die stack package 150. The die stack package 150 includes a substrate 160, a first die stack 170a, a second die stack 170b, a third die stack 170c, and a fourth die stack 170d. The substrate 160 can be coupled to other components not shown (e.g., a package substrate) via interconnections 162 (e.g., solder balls) such that the die stack package 150 can form part of a system-in-package (SiP). Each of the first through fourth die stacks 170a-d is carried by the substrate 160 such that the first through fourth die stacks 170a-d are arranged side-by-side. The first through fourth die stacks 170a-d can each include a plurality of dies 172 (in the illustrated embodiment, each die stack includes eight dies) stacked on top of one another in a cascading arrangement (e.g., forming steps), as illustrated. Also, one or more of the dies 172 in each of the first through fourth die stacks 170a-d can be electrically coupled to the substrate 160 via corresponding wire bonds 180. In particular, the wire bonds 180 can be coupled to portions of the upper surfaces of the one or more dies 172 that are exposed by virtue of the cascading arrangement.

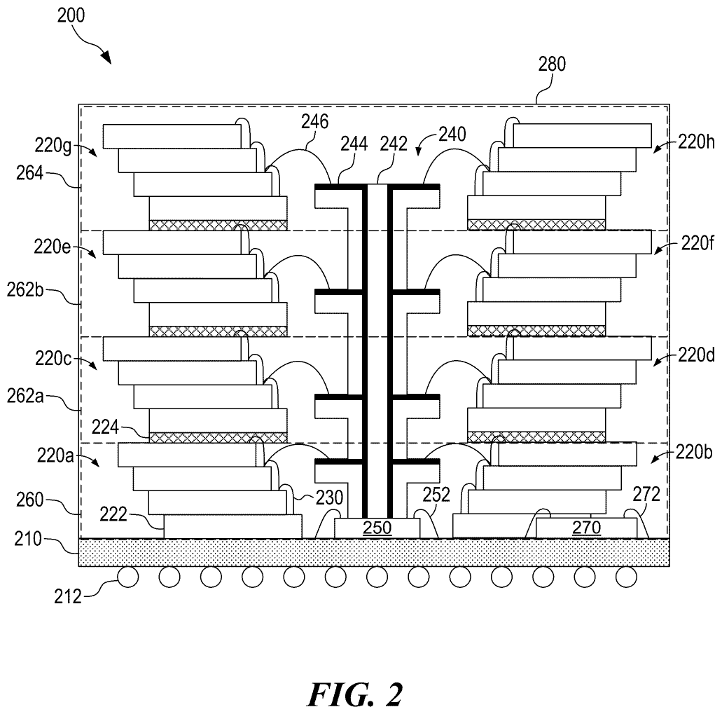

Comparing the die stack package 150 (FIG. 1B) to the die stack package 100 (FIG. 1A), the substrate 160 has a greater lateral dimension (e.g., length, width) than the substrate 110 in order to accommodate double the number of die stacks carried thereon. However, SiPs may not be able to accommodate die stack packages with increased x-y form factors given space constraints. Additionally or alternatively, die stack packages with large lateral dimensions may impose undue constraints on other components of the SiP. Moreover, if a die stack package were to include a greater number of die stacks (e.g., eight, sixteen, etc.), continuously expanding the lateral dimension of the substrate thereof can be impractical. Merely stacking the first die stack 170a on the second die stack 170b and stacking the fourth die stack 170d on the third die stack 170c to continue the cascading arrangement upward would also be impossible. While this can seemingly keep the lateral dimension of the substrate 160 equal to that of the substrate 110, because the first and fourth die stacks 170a cascade upward and toward one another, the first and fourth die stacks 170a would need to occupy the same space. To address these problems and others, embodiments of the present technology provide high die stack packages with modular structures, as illustrated in and discussed below with reference to FIGS. 2-8.

FIG. 2 is a partially schematic cross-sectional diagram of a die stack package 200 configured in accordance with embodiments of the present technology. The die stack package 200 includes a substrate 210 (also referred to herein as “the interposer”), first through eighth die stacks 220a-h (collectively referred to as “the die stacks 220”), and a modular structure 240. The die stack package 200 further includes an input-and-output extender (“IOE”) 250, one or more semiconductor structures 270, and an encapsulant 280.

The substrate 210 can be coupled to other components not shown (e.g., a package substrate) via interconnections 212 (e.g., solder balls) such that the die stack package 200 can form part of a system-in-package (SiP). The first die stack 220a and the second die stack 220b are each carried by the substrate 210 such that the first die stack 220a and the second die stack 220b are arranged side-by-side. The third die stack 220c is carried by the first die stack 220a and the fourth die stack 220d is carried by the second die stack 220b such that the third die stack 220c and the fourth die stack 220d are arranged side-by-side. The fifth die stack 220e is carried by the third die stack 220c and the sixth die stack 220f is carried by the fourth die stack 220d such that the fifth die stack 220e and the sixth die stack 220f are arranged side-by-side. The seventh die stack 220g is carried by the fifth die stack 220e and the eighth die stack 220h is carried by the sixth die stack 220f such that the seventh die stack 220g and the eighth die stack 220h are arranged side-by-side. As discussed further herein, the modular structure 240 is positioned between the die stacks 220 arranged side-by-side and extends in a direction generally parallel to the stacking direction of the first through eighth die stacks 220a-h.

Each of the first through eighth die stacks 220a-h includes a plurality of dies 222 (in the illustrated embodiment, each die stack includes four dies) stacked on top of one another in a cascading arrangement (e.g., forming steps), as illustrated. In particular, the dies 222 of each die stack are stacked to cascade upward and away from the modular structure 240. The dies 222 can include volatile memory dies (e.g., DRAM dies, LPDRAM dies), non-volatile memory dies (e.g., NAND dies, NOR dies, PCM dies, FeRAM dies, MRAM dies), ASIC dies, IOE dies, controller dies, and/or any other suitable dies.

In each die stack, adjacent dies 222 are electrically coupled to one another via corresponding wire bonds 230. The wire bonds 230 can be coupled to portions of the upper surfaces of the dies 222 that are exposed by virtue of the cascading arrangement. Thus, the wire bonds 230 are arranged on the sides of the die stacks 220 facing the modular structure 240. Also, as shown, the third through eighth die stacks 220c-h each includes a dielectric layer 224 (e.g., a silicon oxide layer, film over wire (FOW), and/or the like) at the bottom (e.g., below the bottommost die 222), carried by the die stack below. Each of the dielectric layers 224 can provide space and insulation for the portions of the wire bonds 230 electrically coupling the uppermost die 222 to the die 222 underneath of the die stack below that particular dielectric layer 224.

The IOE 250 (also referred to as “the multiplexer”) is carried by the substrate 210 and positioned in the space between the first and second die stacks 220a, 220b. The IOE 250 can be electrically coupled to the substrate 210 (e.g., to bond pads thereof) via IOE wire bonds 252. The modular structure 240 can be carried by the IOE 250. The modular structure 240 can include an insulating support structure 242 and one or more conducting elements 244 extending therethrough and/or thereon. The insulating support structure 242 can be pre-molded and/or made from epoxy resin or other suitable material (e.g., the same material as the substrate 210). As shown in FIG. 2, the insulating support structure 240 extends upward from the IOE 250 to the space between the seventh and eighth die stacks 220g, 220h, but does not reach the top of the encapsulant 280. The conducting elements 244 extend upward from the IOE 250 through the insulating support structure 242, and extend outward toward each of the die stacks 220. The portions of the conducting elements 244 extending outward can be exposed (e.g., forming bond pads) such that they can be electrically coupled to each of the die stacks 220 (e.g., to at least one of the dies 222 thereof) via modular wire bonds 246.

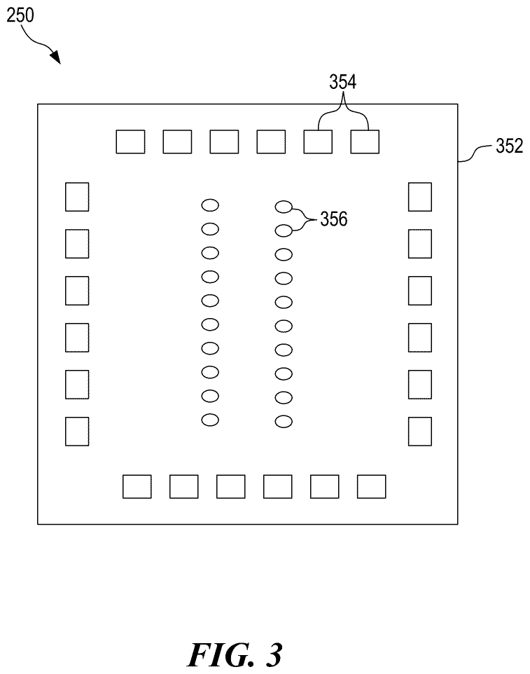

Referring momentarily to FIG. 3, this figure is a partially schematic plan view of the IOE 250 configured in accordance with embodiments of the present technology. The IOE 250 can include a base 352, one or more first bond pads 354 on the base 352, and one or more second bond pads 356 on the base 352. The first bond pads 354 can be arranged along a periphery of the base 352, as shown, and can be shaped and sized to be coupleable to the IOE wire bonds 252 (FIG. 2). The second bond pads 356 can be arranged toward and/or around the center of the base 352, and can be shaped and sized to be coupleable to the conducting elements 244 of the modular structure 240 (FIG. 2).

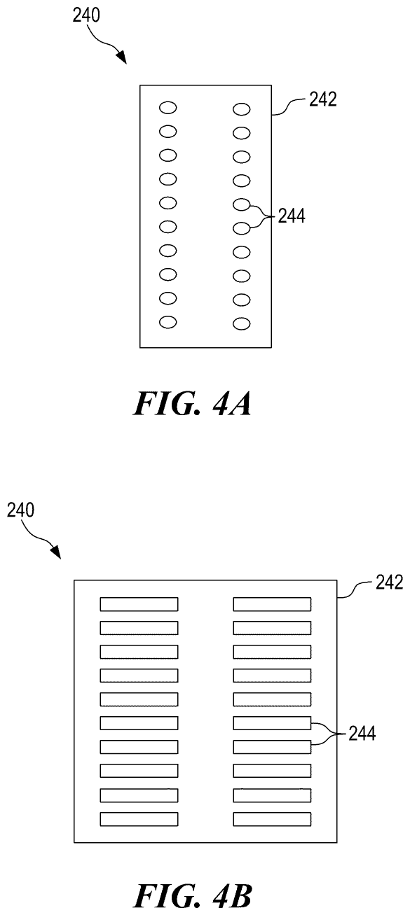

Referring momentarily to FIGS. 4A and 4B, these figures are partially schematic cross-sectional views of the modular structure 240 at (i) a portion in which the conducting elements 244 extend upward through the insulating support structure 242 and (ii) a portion in which the conducting elements 244 extend outwardly toward a pair of die stacks 220, respectively. Comparing FIGS. 4A and 4B, the insulating support structure 242 and the conducting elements 244 each has a smaller cross-sectional dimension in FIG. 4A such that the modular structure 240 can extend upward without requiring excess resources, and has a greater cross-sectional dimension in FIG. 4B such that the modular structure 240 can be positioned closer to each of the die stacks 220 and the conducting elements 244 can provide a sufficient surface area (e.g., forming bond pads) for the modular wire bonds 246 to electrically couple the die stacks 220 to the conducting elements 244. Therefore, returning to FIG. 2, the IOE 250, the IOE wire bonds 252, and the conducting elements 244 of the modular structure 240 electrically couple each of the die stacks 220 to the substrate 210 (and thus other components coupled thereto).

The semiconductor structure 270 is carried by the substrate 210, positioned on a different plane from the die stacks 220, and electrically coupled to the substrate 210 via semiconductor structure wire bonds 272 (or via flip chip). The semiconductor structure 270 can include an Application-Specific Integrated Circuit (ASIC), a capacitor, an inductor, and/or the like. The encapsulant 280 can be disposed over and/or around the substrate 210 to protect and maintain the arrangement of the components of the die stack package 200.

The first die stack 220a, the second die stack 220b, the portion of the modular structure 240 therebetween, and the IOE 250 form a proximal unit 260 (indicated by a dashed box). The third die stack 220c, the fourth die stack 220d, and the portion of the modular structure 240 therebetween form a first modular unit 262a (indicated by a dashed box). The fifth die stack 220e, the sixth die stack 220f, and the portion of the modular structure 240 therebetween form a second modular unit 262b (indicated by a dashed box). The first modular unit 262a and the second modular unit 262b can be collectively referred to as “the modular units 262.” The seventh die stack 220g, the eighth die stack 220h, and the portion of the modular structure 240 therebetween form a distal unit 264 (indicated by a dashed box).

In some embodiments, the first and second die stacks 220a, 220b are referred to as proximal die stacks, the third through sixth die stacks 220c-f are referred to as modular die stacks, and the seventh and eighth die stacks 220g, 220h are referred to as distal die stacks. Also, the portions of the modular structure 240 in the proximal unit 260, the modular units 262, and the distal unit 264 can be referred to as the proximal portion, the modular portions, and the distal portions of the modular structure 240, respectively. Furthermore, the portions of the modular wire bonds 246 in the proximal unit 260, the modular units 262, and the distal unit 264 can be referred to as proximal wire bonds, modular wire bonds, and distal wire bonds, respectively.

As illustrated in FIG. 2, each of the proximal unit 260, the modular units 262, and the distal unit 264 are generally similar in structure, each including a pair of die stacks 220 arranged side-by-side and a portion of the modular structure 240 therebetween. Notably, the proximal unit 260 includes the IOE 250, the modular units 262 are identical or at least substantially similar to one another, and the distal unit 264 includes the terminal portion or end of the modular structure 240, which does not extend to the top of the encapsulant 280.

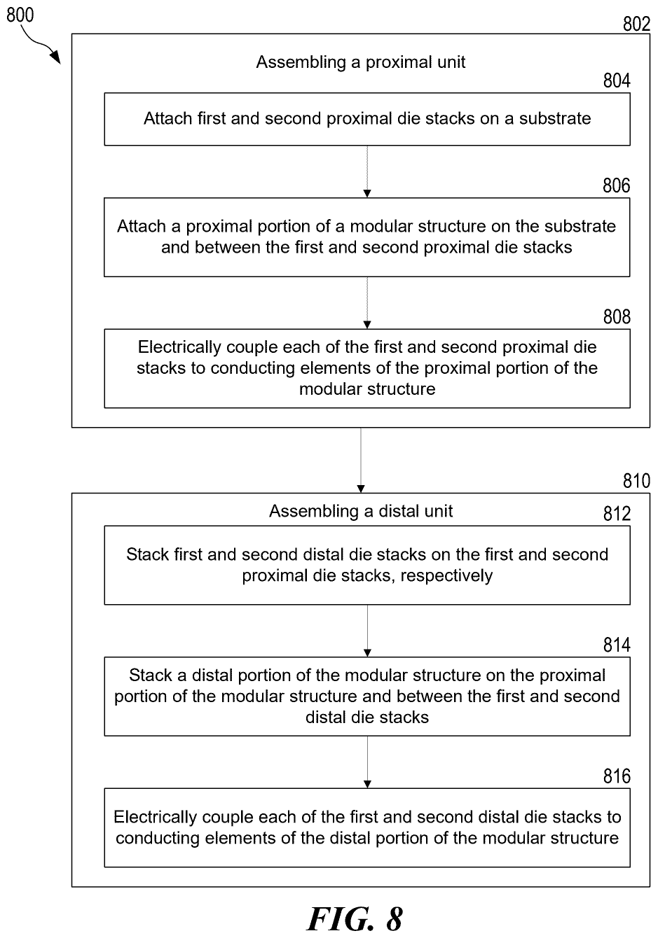

Therefore, as discussed further herein with reference to FIG. 8, each unit 260, 262, 264 can be manufactured independently and assembled together by stacking the proximal unit 260 on the substrate 210, the modular units 262 on the proximal unit 260 and/or on one another, and the distal unit 264 on the modular units 262. The die stack package 200 can include one, three, four, five, six, or more modular units 262 such that the die stack package 200 can include various numbers of dies 222. For example, each die stack 220 can include four dies 222 (as shown) and the die stack package 200 can include six modular units 262 such that the die stack package 200 includes a total of 64 dies 222. Alternatively, each die stack 220 can include eight dies 222 and the die stack package can include two modular units 262 such that the die stack package 200 includes a total of 64 dies 222. In some embodiments, the die stack package 200 omits the modular units 262 and only includes the proximal unit 260 and the distal unit 264 carried by the substrate 210.

By including the modular structure 240 and by having various stackable units (e.g., the units 260, 262, 264), the die stack package 200 can easily stack any number of dies. The modular structure 240 provides the necessary interconnection points (e.g., bond pads) for electrically coupling the other components of the die stack package 200 to one another. The modular structure 240 is also modular, providing an effective and efficient solution to electrically couple the substrate 210 to each of the die stacks 220 regardless of the total height of the die stacks. Furthermore, because the units 260, 262, 264 are stacked on top of one another, the lateral dimension of the substrate 210, which defines the lateral dimension of the die stack package 200, can be smaller than, for example, the lateral dimension of the substrate 160 (FIG. 1B) while the die stack package 200 includes the same number of dies (e.g., 32 dies, as shown).

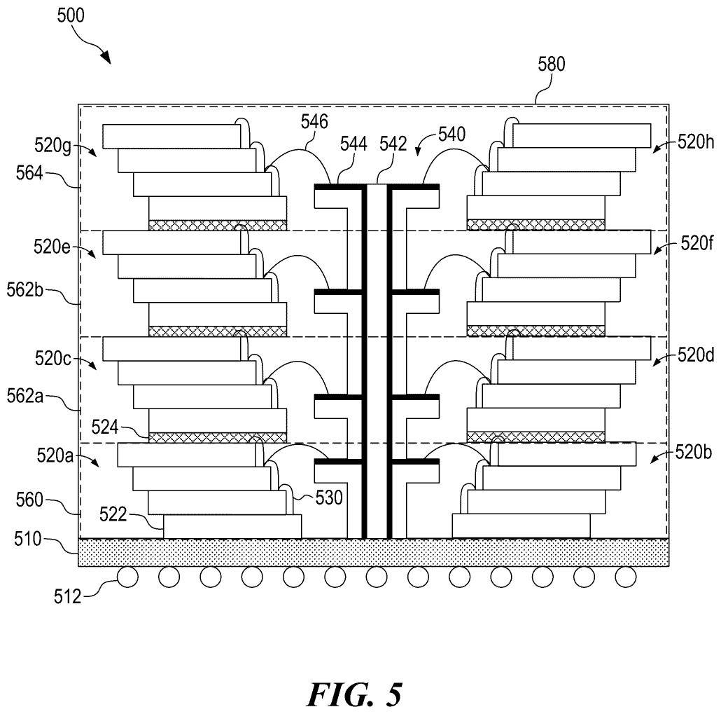

FIG. 5 is a partially schematic cross-sectional diagram of a die stack package 500 configured in accordance with embodiments of the present technology. The die stack package 500 can be generally similar to the die stack package 200 of FIG. 2. For example, the die stack package 500 includes a substrate 510 (also referred to herein as “the interposer”), first through eighth die stacks 520a-h (collectively referred to as “the die stacks 520”), a modular structure 540, and an encapsulant 580. Components of the die stack package 500 can be identical or generally similar in structure and/or function as components of the die stack package 200 of FIG. 2 that are similarly labeled, unless indicated otherwise.

Like in the die stack package 200 of FIG. 2, the substrate 510 can be coupled to other components not shown (e.g., a package substrate) via interconnections 512 (e.g., solder balls) such that the die stack package 500 can form part of a system-in-package (SiP). In each die stack 520, adjacent dies 522 can be electrically coupled via wire bonds 530. The third through eighth die stacks 520c-h can each include a dielectric layer 524. The modular structure 540 can include an insulating support structure 542 and one or more conducting elements 544 extending therethrough and/or thereon. In particular, portions of the conducting elements 544 can extend toward each of the die stacks 520 and be exposed (e.g., form bond pads) such that modular wire bonds 546 can electrically couple each of the die stacks 520 to the conducting elements 544. Also, as similarly discussed above with reference to FIG. 2, the die stack package 500 can include stackable units including a proximal unit 560, one or more modular units 562 (may also be omitted), and a distal unit 564.

Unlike the die stack package 200 of FIG. 2, however, the die stack package 500 does not include an IOE (e.g., the IOE 250). Instead, the modular structure 540 is immediately carried by the substrate 510, and the conducting elements 544 of the modular structure 540 are directly electrically coupled to the substrate 510 (e.g., to bond pads thereof). Also, the die stack package 500 does not include a semiconductor structure (e.g., the semiconductor structure 270).

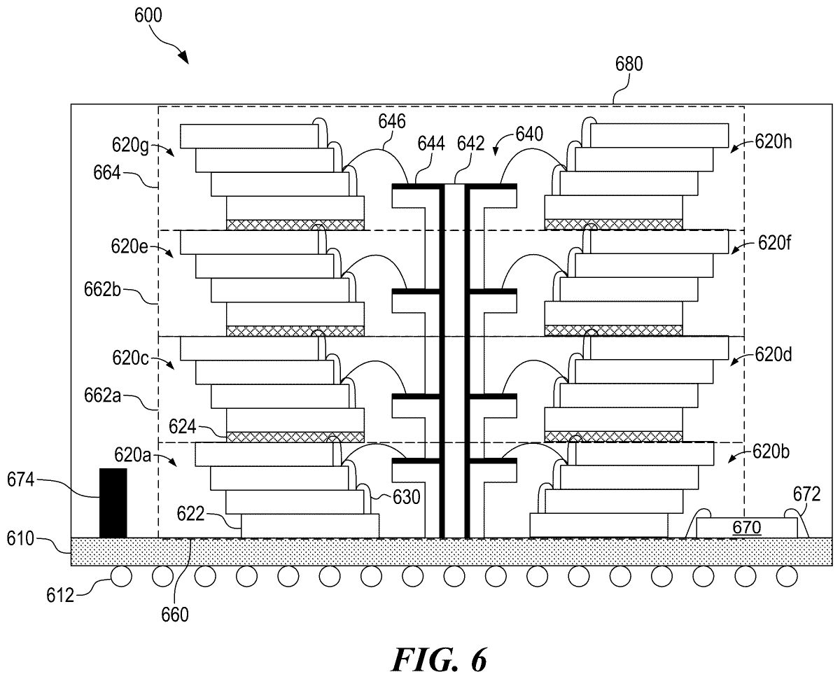

FIG. 6 is a partially schematic cross-sectional diagram of a die stack package 600 configured in accordance with embodiments of the present technology. The die stack package 600 can be generally similar to the die stack package 200 of FIG. 2. For example, the die stack package 600 includes a substrate 610 (also referred to herein as “the interposer”), first through eighth die stacks 620a-h (collectively referred to as “the die stacks 620”), and a modular structure 640. The die stack package 600 further includes a first semiconductor structure 670, a second semiconductor structure 674, and an encapsulant 680. Components of the die stack package 600 can be identical or generally similar in structure and/or function as components of the die stack package 200 of FIG. 2 that are similarly labeled, unless indicated otherwise.

Like in the die stack package 200 of FIG. 2, the substrate 610 can be coupled to other components not shown (e.g., a package substrate) via interconnections 612 (e.g., solder balls) such that the die stack package 600 can form part of a system-in-package (SiP). In each die stack 620, adjacent dies 622 can be electrically coupled via wire bonds 630. The third through eighth die stacks 620c-h can each include a dielectric layer 624. The modular structure 640 can include an insulating support structure 642 and one or more conducting elements 644 extending therethrough and/or thereon. In particular, portions of the conducting elements 644 can extend toward each of the die stacks 620 and be exposed (e.g., form bond pads) such that modular wire bonds 646 can electrically couple each of the die stacks 620 to the conducting elements 644. Also, as similarly discussed above with reference to FIG. 2, the die stack package 600 can include stackable units including a proximal unit 660, one or more modular units 662 (may also be omitted), and a distal unit 664.

Unlike the die stack package 200 of FIG. 2, however, the die stack package 600 does not include an IOE (e.g., the IOE 250). Instead, the modular structure 640 is immediately carried by the substrate 610, and the conducting elements 644 of the modular structure 640 are directly electrically coupled to the substrate 610 (e.g., to bond pads thereof). Also, the lateral dimension of the substrate 610 can be greater than that of the substrate 210 of FIG. 2 such that the first semiconductor structure 670 and the second semiconductor structure 674 can be carried by the substrate 610 on the same plane as the die stacks 620. The first semiconductor structure 670 and/or the second semiconductor structure 674 can include an ASIC, a capacitor, an inductor, and/or the like. The first semiconductor structure 670 can be electrically coupled to the substrate 610 via semiconductor structure wire bonds 672 (or via flip chip). The second semiconductor structure 674 can be electrically coupled to the substrate 610 via wire bonds (not shown) or directly (e.g., like the conducting elements 644 of the modular structure 640). Nevertheless, because the units 660, 662, 664 are stacked on top of one another, the lateral dimension of the substrate 610, which defines the lateral dimension of the die stack package 600, can still be smaller than, for example, the lateral dimension of the substrate 160 (FIG. 1B) while the die stack package 600 includes the same number of dies (e.g., 32 dies, as shown).

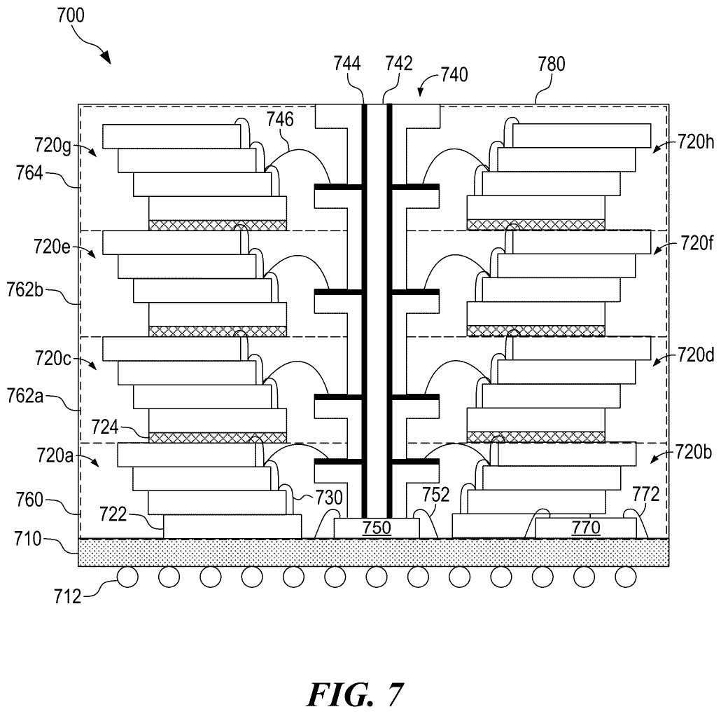

FIG. 7 is a partially schematic cross-sectional diagram of a die stack package 700 configured in accordance with embodiments of the present technology. The die stack package 700 can be generally similar to the die stack package 200 of FIG. 2. For example, the die stack package 700 includes a substrate 710 (also referred to herein as “the interposer”), first through eighth die stacks 720a-h (collectively referred to as “the die stacks 720”), and a modular structure 740. The die stack package 700 further includes an input-and-output extender (“IOE”) 750, one or more semiconductor structures 770, and an encapsulant 780. Components of the die stack package 700 can be identical or generally similar in structure and/or function as components of the die stack package 200 of FIG. 2 that are similarly labeled, unless indicated otherwise.

Like in the die stack package 200 of FIG. 2, the substrate 710 can be coupled to other components not shown (e.g., a package substrate) via interconnections 712 (e.g., solder balls) such that the die stack package 700 can form part of a system-in-package (SiP). In each die stack 720, adjacent dies 722 can be electrically coupled via wire bonds 730. The third through eighth die stacks 720c-h can each include a dielectric layer 724. The modular structure 740 can include an insulating support structure 742 and one or more conducting elements 744 extending therethrough and/or thereon. In particular, portions of the conducting elements 744 can extend toward each of the die stacks 720 and be exposed (e.g., form bond pads) such that modular wire bonds 746 can electrically couple each of the die stacks 720 to the conducting elements 744. Also, as similarly discussed above with reference to FIG. 2, the die stack package 700 can include stackable units including a proximal unit 760, one or more modular units 762 (may also be omitted), and a distal unit 764. The IOE 750 and the semiconductor structure 770 can be electrically coupled to the substrate 710 via IOE wire bonds 752 and semiconductor structure wire bonds 772 (or via flip chip), respectively.

Unlike in the die stack package 200 of FIG. 2, however, the modular structure 740 extends upward and reaches the top of the encapsulant 780 such that the conducting elements 744 are exposed at the top. Therefore, the exposed portions of the conducting elements 744 can be used for testing, debugging, and/or the like before the die stack package 700 is finalized. After testing, debugging, and/or the like, the portion of the modular structure 740 exposed at the top can be covered with an additional layer of the encapsulant 780 for protection.

Referring to FIGS. 2-7 together, embodiments of the present technology provide a scalable die stack package that can include more than eight die stacks. For example, as aforementioned, a die stack package can include three, four, five, six, or more modular units (e.g., the modular units 262, 562, 662, 762). Thus, one of ordinary skill in the art will appreciate that die stack packages configured in accordance with embodiments of the present technology can include a wide range of number of dies and die stacks while maintaining an x-y form factor smaller than that of conventional packages including the same number of dies and die stacks (e.g., the die stack package 150 of FIG. 1B).

Die stack packages configured in accordance with embodiments of the present technology also provide high manufacturability, electrical reliability, and debugging ability. First, the die stack packages illustrated and described herein can be manufactured with commonly available and/or easily modifiable components, such as wires and interposers. Second, the electrical signals are communicated to and from the dies directly through the substrate and/or through the IOE, thereby maintaining the integrity of the signals. Third, referring to, e.g., the die stack package 700 of FIG. 7, the modular structure can be exposed (e.g., not fully covered by the encapsulant), thereby allowing the die stacks to be tested, debugged, and/or the like quickly and efficiently.

FIG. 8 is a flowchart illustrating a method 800 for manufacturing a die stack package in accordance with some embodiments of the present technology. While the steps of the method 800 are described below in a particular order, one or more of the steps can be performed in a different order or omitted, and the method 800 can include additional and/or alternative steps. Additionally, although the method 800 may be described below with reference to the embodiments of the present technology described herein, the method 800 can be performed with other embodiments of the present technology.

The method 800 begins at block 802 by assembling a proximal unit (e.g., the proximal unit 260). To assemble the proximal unit, at block 804, the method 800 continues within block 802 by attaching first and second proximal die stacks (e.g., the first and second die stacks 220a, 220b) on a substrate (e.g., the substrate 210). At block 806, the method 800 continues within block 802 by attaching a proximal portion of a modular structure (e.g., the modular structure 240) on the substrate and between the first and second proximal die stacks. At block 808, the method 800 continues within block 802 by electrically coupling each of the first and second proximal die stacks to conducting elements (e.g., the conducting elements 244) of the proximal portion of the modular structure. In some embodiments, each of the first and second proximal die stacks are electrically coupled to the conducting elements via modular wire bonds (e.g., the modular wire bonds 246).

At block 810, the method 800 continues by assembling a distal unit (e.g., the distal unit 264). To assemble the distal unit, at block 812, the method 800 continues within block 810 by stacking first and second distal die stacks (e.g., the seventh and eighth die stacks 220g, 220h) on the first and second proximal die stacks, respectively. At block 814, the method 800 continues within block 810 by stacking a distal portion of the modular structure on the proximal portion of the modular structure and between the first and second distal die stacks. At block 816, the method 800 continues within block 810 by electrically coupling each of the first and second distal die stacks to conducting elements of the distal portion of the modular structure. In some embodiments, each of the first and second distal die stacks are electrically coupled to the conducting elements via modular wire bonds (e.g., the modular wire bonds 246).

In some embodiments, the method 800 further comprises assembling (e.g., prior to assembling the distal unit) one or more modular units (e.g., the modular units 262). Assembling each of the one or more modular units can comprise (i) stacking first and second modular die stacks (e.g., the third through sixth die stacks 220c-f) on the first and second proximal die stacks or other first and second modular die stacks, respectively, (ii) stacking a modular portion of the modular structure on the proximal portion or another modular portion of the modular structure and between the first and second distal die stacks, and (iii) electrically coupling each of the first and second modular die stacks to conducting elements of the modular portion of the modular structure.

In some embodiments, stacking the first and second distal die stacks comprises (i) stacking first and second dielectric layers on the first and second proximal die stacks, respectively, and (ii) stacking first and second pluralities of dies on the first and second dielectric layers, respectively. In some embodiments, each of the first and second modular die stacks are electrically coupled to the conducting elements via modular wire bonds (e.g., the modular wire bonds 246).

In some embodiments, the method 800 further comprises (i) attaching an input-and-output extender (e.g., the IOE 250) on the substrate, wherein the proximal portion of the modular structure is attached on the IOE such that the conducting elements of the proximal portion of the modular structure are electrically coupled to the IOE, and (ii) electrically coupling the IOE to the substrate. In some embodiments, the method 800 further comprises attaching one or more semiconductor structures on the substrate, wherein the one or more semiconductor structures include at least one of an Application-Specific Integrated Circuit (ASIC), a capacitor, or an inductor.

In some embodiments, the method 800 further comprises (i) forming an encapsulant around the proximal unit and the distal unit, wherein the encapsulant is formed such that portions of the conducting elements of the distal portion of the modular structure are not covered by the encapsulant, and (ii) debugging (e.g., testing) at least one of the first proximal die stack, the second proximal die stack, the first distal die stack, or the second distal die stack via the portions of the conducting elements of the distal portion of the modular structure not covered by the encapsulant.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

I/We claim:

1. A die stack package, comprising:
a substrate;
a proximal unit carried by the substrate, wherein the proximal unit includes:
a first proximal die stack carried by the substrate;
a second proximal die stack carried by the substrate;
a proximal portion of a modular structure carried by the substrate and positioned between the first and second proximal die stacks, wherein the modular structure includes conducting elements electrically coupled to the substrate; and
proximal wire bonds electrically coupling each of the first and second proximal die stacks to the conducting elements of the modular structure; and
a distal unit carried by the proximal unit, wherein the distal unit includes:
a first distal die stack carried by the first proximal die stack;
a second distal die stack carried by the second proximal die stack, wherein each of the first and second proximal die stacks and the first and second distal die stacks includes a plurality of dies;
a distal portion of the modular structure carried by the proximal portion of the modular structure and positioned between the first and second distal die stacks; and
distal wire bonds electrically coupling each of the first and second distal die stacks to the conducting elements of the modular structure.

2. The die stack package of claim 1, further comprising one or more modular units stacked between the proximal unit and the distal unit, wherein each of the one or more modular units includes:
a first modular die stack carried by the first proximal die stack;
a second modular die stack carried by the second proximal die stack;
a modular portion of the modular structure carried by the proximal portion of the modular structure and positioned between the first and second modular die stacks; and
modular wire bonds electrically coupling each of the first and second modular die stacks to the conducting elements of the modular structure.

3. The die stack package of claim 2, wherein the first distal die stack, the second distal die stack, the first modular die stack, and the second modular die stack each further comprises a dielectric layer disposed below a bottommost die of the first distal die stack or the first modular die stack.

4. The die stack package of claim 1, further comprising an input-and-output extender (IOE) carried by the substrate, wherein the modular structure is carried by the IOE, and wherein the IOE is electrically coupled to the substrate and to the conducting elements of the modular structure.

5. The die stack package of claim 4, wherein the IOE comprises a base, a plurality of first bond pads positioned along a periphery of the base and coupleable to IOE wire bonds electrically coupling the IOE to the substrate, and a plurality of second bond pads positioned around a center of the base and coupleable to the conducting elements of the modular structure.

6. The die stack package of claim 1, further comprising one or more semiconductor structures carried by the substrate and positioned on a different plane than the first and second proximal die stacks, wherein the one or more semiconductor structures include at least one of an Application-Specific Integrated Circuit (ASIC), a capacitor, or an inductor.

7. The die stack package of claim 1, further comprising one or more semiconductor structures carried by the substrate and positioned on a same plane as the first and second proximal die stacks, wherein the one or more semiconductor structures include at least one of an Application-Specific Integrated Circuit (ASIC), a capacitor, or an inductor.

8. The die stack package of claim 1, further comprising an encapsulant formed around the first and second proximal die stacks and the first and second distal die stacks, wherein the distal portion of the modular structure extends to a top of the die stack package such that portions of the conducting elements of the modular structure are not covered by the encapsulant at the top of the die stack package.

9. The die stack package of claim 1, wherein the modular structure further includes an insulating support structure extending between the proximal and distal portions of the modular structure, wherein corresponding portions of the insulating support structure extend outward toward each of the first and second proximal die stacks and the first and second distal die stacks, and wherein portions of the conducting elements extend outward along the corresponding portions of the insulating support structure to be electrically coupled to each of the first and second proximal die stacks and the first and second distal die stacks.

10. The die stack package of claim 1, wherein the dies of each of the first and second proximal die stacks and the first and second distal die stacks are arranged to cascade upward and away from the modular structure.

11. The die stack package of claim 1, further comprising wire bonds electrically coupling each of the dies of each of the first and second proximal die stacks and the first and second distal die stacks to adjacent ones of the dies.

12. The die stack package of claim 1, wherein each of the first and second proximal die stacks and the first and second distal die stacks includes four dies.

13. A die stack package, comprising:
an interposer;
a plurality of first die stacks carried by the interposer, wherein the first die stacks are stacked on top of one another;
a plurality of second die stacks carried by the interposer, wherein the second die stacks are stacked on top of one another; and
a modular structure carried by the interposer, wherein the modular structure extends into spaces between the plurality of first die stacks and the plurality of second die stacks, wherein the modular structure includes conducting elements electrically coupled to each of the first die stacks, each of the second die stacks, and the interposer.

14. The die stack package of claim 13, further comprising an input-and-output extender (IOE) carried by the interposer, wherein the modular structure is carried by the IOE, wherein the IOE is electrically coupled to the interposer via IOE wire bonds, and wherein the IOE is directly electrically coupled to conducting elements of the modular structure.

15. A method for manufacturing a die stack package, the method comprising:
assembling a proximal unit, wherein assembling the proximal unit comprises:
attaching first and second proximal die stacks on a substrate;
attaching a proximal portion of a modular structure on the substrate and between the first and second proximal die stacks; and
electrically coupling each of the first and second proximal die stacks to conducting elements of the proximal portion of the modular structure; and
assembling a distal unit, wherein assembling the distal unit comprises:
stacking first and second distal die stacks on the first and second proximal die stacks, respectively;
stacking a distal portion of the modular structure on the proximal portion of the modular structure and between the first and second distal die stacks; and
electrically coupling each of the first and second distal die stacks to conducting elements of the distal portion of the modular structure.

16. The method of claim 15, further comprising:
assembling, prior to assembling the distal unit, one or more modular units, wherein assembling each of the one or more modular units comprises:
stacking first and second modular die stacks on the first and second proximal die stacks or other first and second modular die stacks, respectively;
stacking a modular portion of the modular structure on the proximal portion or another modular portion of the modular structure and between the first and second distal die stacks; and
electrically coupling each of the first and second modular die stacks to conducting elements of the modular portion of the modular structure.

17. The method of claim 15, further comprising:
attaching an input-and-output extender (IOE) on the substrate, wherein the proximal portion of the modular structure is attached on the IOE such that the conducting elements of the proximal portion of the modular structure are electrically coupled to the IOE; and
electrically coupling the IOE to the substrate.

18. The method of claim 15, wherein stacking the first and second distal die stacks comprises:
stacking first and second dielectric layers on the first and second proximal die stacks, respectively; and
stacking first and second pluralities of dies on the first and second dielectric layers, respectively.

19. The method of claim 15, further comprising:
forming an encapsulant around the proximal unit and the distal unit, wherein the encapsulant is formed such that portions of the conducting elements of the distal portion of the modular structure are not covered by the encapsulant; and
debugging at least one of the first proximal die stack, the second proximal die stack, the first distal die stack, or the second distal die stack via the portions of the conducting elements of the distal portion of the modular structure not covered by the encapsulant.

20. The method of claim 15, further comprising:
attaching one or more semiconductor structures on the substrate, wherein the one or more semiconductor structures include at least one of an Application-Specific Integrated Circuit (ASIC), a capacitor, or an inductor.
